(19) United States
(12) Patent Application Publication
(10) Pub. No.: US 2026/0248016 A1
(43) Pub. Date: Aug. 20, 2026

(54) ELECTRONIC COMPONENT AND EQUIPMENT INCLUDING ELECTRONIC COMPONENT

(71) Applicant: CANON KABUSHIKI KAISHA, Tokyo (JP)

(72) Inventor: YU KATASE, Kanagawa (JP)

(21) Appl. No.: 19/541,688

(22) Filed: Feb. 17, 2026

(30) Foreign Application Priority Data
Feb. 20, 2025 (JP) 2025-026031

(51) Int. Cl. H10W 72/50; H10W 72/00; H10W 90/00

(52) U.S. Cl. CPC H10W 72/5522; H10W 72/0198; H10W 72/536; H10W 72/5449; H10W 90/00; H10W 90/724; H10W 90/734; H10W 90/756

(57) ABSTRACT

An electronic component comprises a semiconductor substrate; a base; a cooling component, and a plate member including a wiring. The plate member is arranged between a cold side of the cooling component and the semiconductor substrate, the base is arranged on a hot side of the cooling component, a first electrode is arranged on the semiconductor substrate, a second electrode and a third electrode are arranged on the plate member, and a fourth electrode is arranged on the base, the second electrode and the third electrode are connected by the wiring of the plate member, the first electrode and the second electrode are connected by a first bonding wire, and the third electrode and the fourth electrode are connected by a second bonding wire.

### BACKGROUND

### Field of the Technology

The present disclosure relates to an electronic component and equipment including an electronic component.

### Description of the Related Art

Japanese Patent Laid-Open No 2006-191465 discloses electronic equipment including a Peltier element and an image capturing element.

### SUMMARY

The present disclosure provides an electronic component having a structure capable of suppressing temperature rise.

According to one aspect of the disclosure, there is provided an electronic component comprises a semiconductor substrate; a base; a cooling component, and a plate member including a wiring, wherein the plate member is arranged between a cold side of the cooling component and the semiconductor substrate, the base is arranged on a hot side of the cooling component, a first electrode is arranged on the semiconductor substrate, a second electrode and a third electrode are arranged on the plate member, and a fourth electrode is arranged on the base, the second electrode and the third electrode are connected by the wiring of the plate member, the first electrode and the second electrode are connected by a first bonding wire, and the third electrode and the fourth electrode are connected by a second bonding wire, and at least a part of the wiring of the plate member overlaps a region in which the cooling component is arranged in a planar view.

Features of the present disclosure will become apparent from the following description of embodiments with reference to the attached drawings. The following description of embodiments is described by way of example.

### BRIEF DESCRIPTION OF THE DRAWINGS

The accompanying drawings, which are incorporated in and constitute a part of the specification, illustrate embodiments of the present disclosure, and together with the description, serve to explain the principles of the embodiments.

FIG. 1 is a schematic sectional view of an electronic component according to the first embodiment;

FIG. 2 is a schematic plan view of the electronic component according to the first embodiment;

FIG. 3A is a schematic bottom view of the electronic component according to the first embodiment;

FIG. 3B is a schematic bottom view of the electronic component according to the first embodiment;

FIG. 4 is a schematic view of the electronic component according to the first embodiment;

FIG. 5A is a schematic view of a plate member according to the first embodiment;

FIG. 5B is a schematic view of the plate member according to the first embodiment;

FIG. 5C is a schematic view of the plate member according to the first embodiment;

FIG. 5D is a schematic view of the plate member according to the first embodiment;

FIG. 6A is a schematic sectional view of an electronic component according to the second embodiment;

FIG. 6B is a schematic sectional view of the electronic component according to the second embodiment;

FIG. 7A is a schematic plan view of the electronic component according to the second embodiment;

FIG. 7B is a schematic plan view of the electronic component according to the second embodiment;

FIG. 8A is a view for explaining a method of forming a bonding wire of the electronic component according to the second embodiment;

FIG. 8B is a view for explaining a method of forming a bonding wire of the electronic component according to the second embodiment;

FIG. 9 is a view for explaining a method of forming a bonding wire of the electronic component according to the second embodiment;

FIG. 10 is a schematic sectional view of an electronic component according to the third embodiment;

FIG. 11 is a schematic plan view of the electronic component according to the third embodiment;

FIG. 12 is a schematic view of the electronic component according to the third embodiment;

FIG. 13A is a schematic view of a plate member according to the third embodiment;

FIG. 13B is a schematic view of the plate member according to the third embodiment;

FIG. 13C is a schematic view of the plate member according to the third embodiment;

FIG. 13D is a schematic view of the plate member according to the third embodiment;

FIG. 14A is a schematic sectional view of an electronic component according to the fourth embodiment;

FIG. 14B is a schematic sectional view of the electronic component according to the fourth embodiment;

FIG. 15A is a schematic plan view of the electronic component according to the fourth embodiment;

FIG. 15B is a schematic plan view of the electronic component according to the fourth embodiment; and

FIG. 16 is a view for explaining an example in which the electronic component according to the present disclosure is applied to equipment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

Embodiments will now be described in detail with reference to the accompanying drawings. Note that in the following explanation, terms indicating a specific direction or position (for example, terms “upper”, “lower”, “right”, and “left”, and other terms including these terms) are used as needed. Use of these terms aims at facilitating understanding of embodiments with reference to the drawings, and the meanings of the terms do not limit the technical scope of the present disclosure.

In this specification, “viewed in a planar view” indicates viewing from a direction perpendicular to the light incident surface of a semiconductor layer. In a case where an optical member is arranged on the side where light enters, viewing is done from the optical member or from the opposite side. Also, “cross section” indicates a surface in the direction perpendicular to the light incident surface of the semiconductor layer. Note that if the light incident surface of the semiconductor layer is a coarse surface microscopically, a planar view is macroscopically defined with respect to the light incident surface of the semiconductor layer as a reference.

The semiconductor layer has a first surface from which light enters, and a second surface on the opposite side of the first surface. In this specification, if a photodiode (PD) is arranged in the semiconductor layer, the depth direction is a direction from the first surface to the second surface of the semiconductor layer. The “depth” of a certain point or a certain region in the semiconductor layer means the distance of the point or region from the first surface. If there are a point (or region) Z1 whose distance (depth) from the first surface is d1 and a point (or region) Z2 whose distance (depth) from the first surface is d2, and d1>d2 holds, this may be expressed as “Z1 is deeper than Z2” or “Z2 is shallower than Z1”. Also, if there is a point (or region) Z3 whose distance (depth) from the first surface is d3, and d1>d3>d2 holds, this may be expressed as “Z3 exists at a depth between Z1 and Z2” or “Z3 exists between Z1 and Z2 concerning the depth direction”.

In this specification, expressions such as “A or B”, “at least one of A and B”, “at least one of A or/and B”, and “one or more of A or/and B” can include all combinations of listed items unless explicitly defined. That is, it is understood that the above expressions disclose all cases where at least one A is included, a case where at least one B is included, and a case where both at least one A and at least one B are included. This similarly applies to a combination of three or more elements.

The contents disclosed in this specification include complements of concepts described in this specification. That is, it can be said that in a case where the specification states that, for example, “A is larger than B”, the specification discloses that “A is not larger than B” even if “A is not larger than B” is omitted. This is because the statement “A is larger than B” presupposes a case where “A is not larger than B”.

### First Embodiment

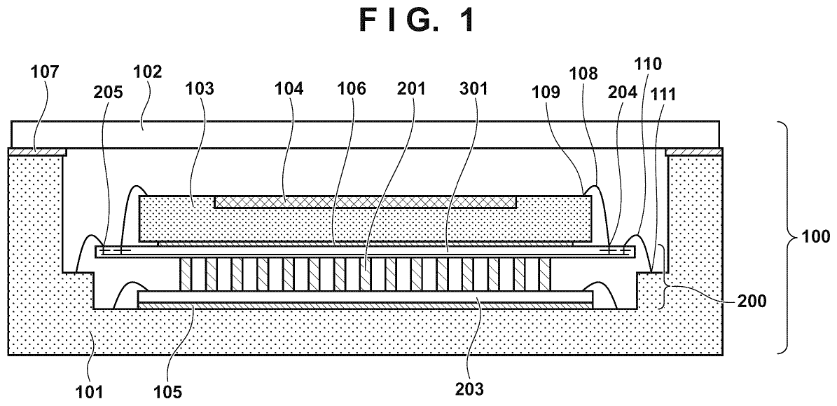

An electronic component according to the embodiment of the present disclosure will be described with reference to FIGS. 1 to 5. The characteristic of a semiconductor chip stored in a package may be changed by heat generation. In a case of an electronic component on which a photoelectric conversion element is mounted as an image capturing element, noise may be generated in the output of the photoelectric conversion element due to a temperature change. To reduce the noise, a cooling component for cooling the semiconductor chip may be placed in a package in which the semiconductor chip with the photoelectric conversion element is placed. One of members used to cool the semiconductor chip is a Peltier element. In the following embodiment, an electronic component including a photoelectric conversion element and a Peltier element serving as a cooling component will be described, but the element mounted on the semiconductor chip is not limited to the photoelectric conversion element. Also, the cooling component is not limited to the Peltier element and may be a cooling fin or a heat pipe.

This embodiment will be described with reference to a sectional view showing an example of the configuration of an electronic component shown in FIG. 1. The electronic component may include a base 101, and a package 100 including an optical member 102 adhered to the frame body of the base 101 by an optical member adhesive 107. Also, the electronic component may include the base 101, a semiconductor substrate 103, a cooling component 200, and a plate member 301.

In this embodiment, the cooling component 200 is adhered to the bottom portion of the base 101 by a cooling portion adhesive 105, and the semiconductor substrate 103 is adhered by a semiconductor substrate adhesive 106. Also, the semiconductor substrate 103 is electrically connected to the base 101 by a first bonding wire 108 and a second bonding wire 110 via the plate member 301 on the cold side of the cooling component 200. The base 101 is formed using, for example, a ceramic such as alumina or aluminum nitride as the main material. Since these materials each have a high thermal conductivity, heat generated by the cooling component 200 can easily be dissipated to the outside of the package

The optical member 102 is made of glass, quartz, sapphire, or the like. Quartz and sapphire can also function as a low-pass filter (LPF). Sapphire is stronger than quartz and can be thinner. That is, it is advantageous in reducing the size of the overall package 100. Also, the linear expansion coefficient of sapphire is substantially the same as the linear expansion coefficient of alumina. For this reason, if the base 101 is made of alumina, reliability in regards to adhesion can be increased by forming the optical member 102 using sapphire.

The semiconductor substrate 103 is, for example, a silicon substrate, and a pixel region 104 in which a plurality of photoelectric conversion elements can be arranged in an array is provided. The photoelectric conversion element may be, for example, a CMOS image sensor or an avalanche diode. If the photoelectric conversion element is an avalanche diode, it may be a single photon avalanche diode (SPAD).

As the cooling portion adhesive 105 and the semiconductor substrate adhesive 106, a material having a high thermal conductivity, for example, silver paste can be used. If a space is generated on the adhesion surface, it impedes heat conduction. Hence, the adhesive can be applied to as large an area of the adhesion surface as possible, or to the whole surface. The adhesive thickness of the cooling portion adhesive 105 or the semiconductor substrate adhesive 106 is about 100 μm or less and advantageously about 20 to 30 μm.

As the optical member adhesive 107, an epoxy-based adhesive can be used. An ultraviolet curing adhesive or a heat curing adhesive can be used. Since the inside of the package 100 is sometimes held in an N₂, Ar, or Xe atmosphere or vacuum for heat insulation, it is advantageous to use an adhesive with low moisture permeability such that it can maintain airtightness.

To keep the moisture permeability low, it is appropriate that the adhesive thickness of the optical member adhesive 107 is thin and the adhesive width is wide. For example, the thickness of the optical member adhesive 107 can be 20 to 30 μm or less. The adhesive width can be set from the viewpoint of reliability in regards to size reduction and adhesion of the package 100 and moisture permeability.

The cooling component 200 is formed by a cooling portion 201 in which a metal electrode, a p-type semiconductor, and an n-type semiconductor are alternately connected, the plate member 301 arranged on the upper side of a region where the cooling portion 201 is arranged, and a lower plate 203 arranged on the lower side of the region where the cooling portion 201 is arranged. The plate member 301 is arranged between the cooling portion 201 and the semiconductor substrate 103, and the lower plate 203 is arranged between the cooling portion 201 and the bottom portion of the base 101.

In this embodiment, a plurality of wirings can be stacked on the plate member 301. Also, the plate member 301 is arranged on a surface (to be referred to as a “cold surface” hereinafter) of the cooling portion 201 on the cold side, and the lower plate 203 is arranged on a surface (to be referred to as a “hot surface” hereinafter) of the cooling portion 201 on the hot side. In the electronic component according to this embodiment, the plate member 301 arranged on the cold side is arranged facing the semiconductor substrate 103, and the lower plate 203 arranged on the hot side is arranged facing the base 101. The plate member 301 and the lower plate 203 use alumina or aluminum nitride as the main material. The surface of the plate member 301 or the lower plate 203 may be treated by gold plating or the like to improve heat conduction. The cooling component 200 has a conduction space including an electrode (not shown) for conduction with the outside. The electrode can be an electrode connected to a power supply or an electrode connected to ground.

Heat absorption will be described based on an example in which a Peltier element is used as the cooling component 200. If a voltage V is applied to the Peltier element, a current I flows. Let T_{c} be a cold surface temperature, and Tₕ be a hot surface temperature. Letting α be a Seebeck coefficient, R be an internal resistance, λ be a thermal conductivity, and ΔT be the temperature difference between the temperature T_{c} of the cold surface and the temperature Tₕ of the heat dissipation surface, heat absorption Qc is represented by

$${Q}_{c} = α {T}_{c} I - λ Δ T - \frac{1}{2} {RI}^{2}$$

That is, to increase heat absorption Qc of the Peltier element, the thermal conductivity λ and the internal resistance R should be small. In a standard Peltier element, the thermal conductivity λ can be made small by reducing the area of the plate member 301. However, since Qc decreases along with this, it is important to select a Peltier element having an appropriate number of p-type semiconductors and n-type semiconductors.

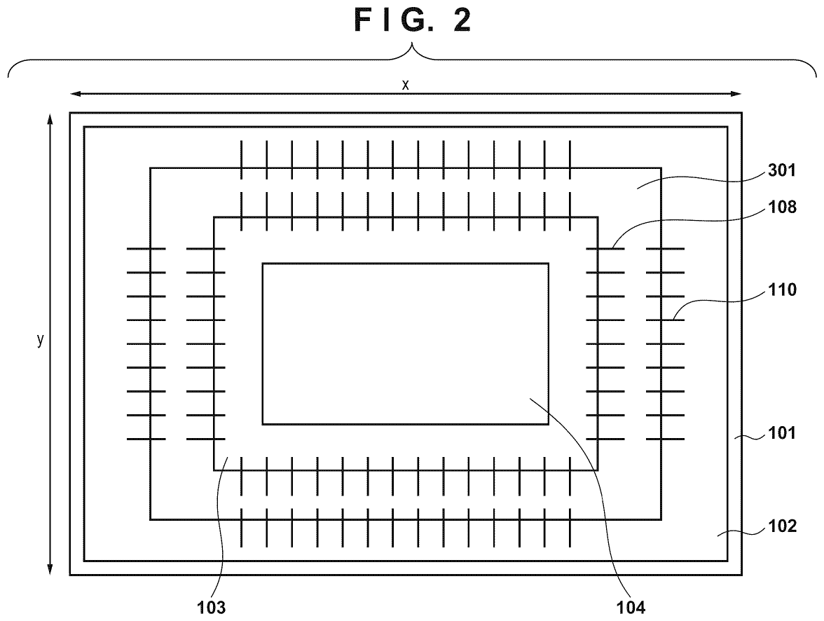

This embodiment will be described with reference to FIG. 2 that shows a planar view of the electronic component according to this embodiment viewed from the side of the optical member 102. The semiconductor substrate 103 having a rectangular shape is arranged at the center of the electronic component, and the pixel region 104 can be arranged on the semiconductor substrate 103. A plurality of first bonding wires 108 are provided on each side of the semiconductor substrate 103, thereby connecting electrodes on the semiconductor substrate 103 and electrodes on the plate member 301 of the cooling component 200. Furthermore, the electrodes on the plate member 301 and electrodes provided on the base 101 are connected by a plurality of second bonding wires 110. Here, letting x be the length of the electronic component in the longitudinal direction and y be the length in the widthwise direction, an electronic component in which both x and y are about 20 mm is assumed, however, the size of the electronic component is not limited to this.

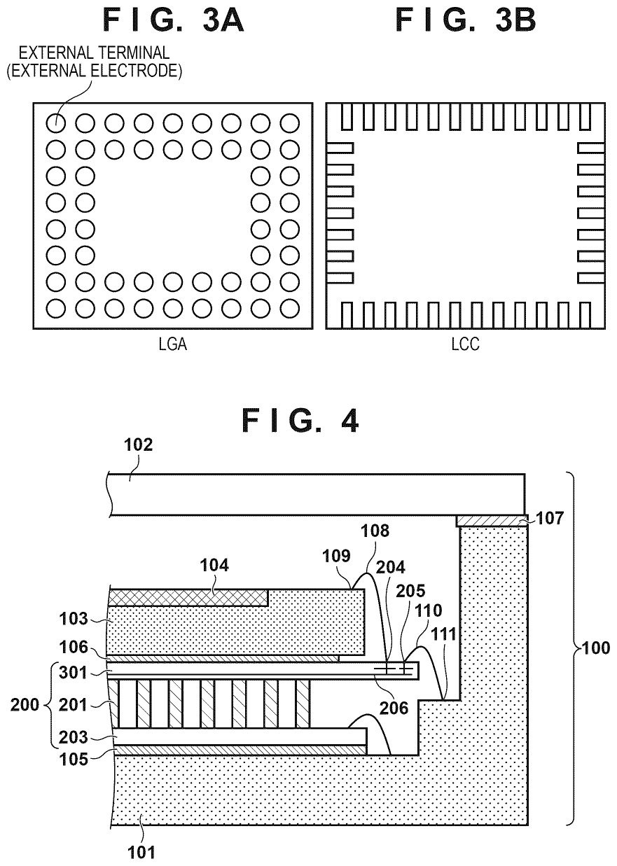

FIGS. 3A and 3B each show a planar view of the electronic component according to this embodiment viewed from the side opposite to the optical member 102. Here, two types of packages are shown as examples. FIG. 3A is a schematic view in a case where the package 100 is so-called land grid array (LGA), and FIG. 3B is a schematic view in a case where the package 100 is so-called leadless ceramic chip carrier (LCC).

The configuration of the electrodes to be connected to the outside of the package 100 can be LGA or LCC, and may be pin grid array (PGA). In a case of LGA, the height can be reduced as compared to other configurations and, therefore, LGA is advantageous from the viewpoint of size reduction. Also, a configuration that combines LGA and LCC may be employed.

If the configuration of the package 100 is LGA, manufacturing using a reflow furnace is possible, and productivity can be expected to improve as compared to other methods. However, to prevent solder contained in the cooling component 200 from melting in the reflow furnace and damaging the cooling component 200, a low-temperature reflow furnace can be used to manufacture the electronic component according to this embodiment. The temperature of the reflow furnace may be lower than the solder melting temperature of the cooling component 200, that is, 200° C. or less. Hence, connection of the Peltier element and the outside can be implemented using a material having a low melting temperature such as resin-reinforced solder.

If the configuration of the package is LGA, as for the terminal array of LGA, a portion without terminals can be provided at the central portion of the package, as shown in FIG. 3A. A member with high thermal conductivity is attached to the portion without terminals, and heat of the base 101 is released to the outside, thereby increasing the cooling efficiency of the cooling component 200. As the member with high thermal conductivity, for example, a carbon graphite sheet, an alloy plate for heat spreader, a heat pipe, or the like can be used.

FIG. 4 is a schematic view showing the base 101, the cooling component 200, and the vicinity of the connection point of the first bonding wire 108 and the second bonding wire 110 of the electronic component according to this embodiment in an enlarged state. A first electrode 109 is provided on the semiconductor substrate 103. A second electrode 204 and a third electrode 205 are provided on the plate member 301. A fourth electrode 111 is provided on the base 101. The second electrode 204 and the third electrode 205 are located outside the outer edge of the semiconductor substrate 103 in a planar view from the side of the optical member 102. The first electrode 109 provided on the semiconductor substrate 103 and the second electrode 204 provided on the plate member 301 are connected by the first bonding wire 108. The third electrode 205 is provided on the plate member 301, and the third electrode 205 and the fourth electrode 111 provided on the base 101 are connected by the second bonding wire 110.

The second electrode 204 and the third electrode 205 are connected by a wiring 206 arranged in the plate member 301, and the semiconductor substrate 103 and the base 101 are electrically connected via the plate member 301. The plate member 301 that is a part of the cooling component 200 is the relay point of the wiring. In an electronic component in which a semiconductor substrate placed on a cooling component such as a Peltier element and a package with the semiconductor substrate placed therein are wire-bonded, a heat flow may occur in which heat on the hot side of the cooling component returns from the package to the substrate via a wire. A heat flow transmitted from the lower plate 203 that is the hot surface to the second bonding wire 110 via the base 101 is cooled by the plate member 301 cooled by the cooling portion 201. For this reason, the heat flow returning to the semiconductor substrate 103 can be suppressed as compared to a configuration in which an electrode on the semiconductor substrate 103 and an electrode on the base 101 are directly connected by a bonding wire.

It is advantageous that the second bonding wire 110 has a high thermal resistance. Since the heat flow transmitted to the plate member 301 can be suppressed, power consumption of the cooling component 200 can be suppressed. As a method of increasing the thermal resistance of the second bonding wire 110, for example, the wire diameter is reduced, the wire length is increased, or the wire is made of a material with low thermal conductivity. As the material of the wire, Cu, Ag, Au, or Al, or an alloy containing these as a main material can be selected. To lower the thermal conductivity, it is better to select an Au alloy over Au or select Al over an Au alloy. To prevent disconnection, the wire diameters of the first bonding wire 108 and the second bonding wire 110 are decided by balance of an allowable current amount, an electric resistance, an inductance, and the like.

On the other hand, the wiring length between the semiconductor substrate 103 and the base 101 is the sum of the length of the first bonding wire 108+the length of the wiring 206 connecting the second electrode 204 and the third electrode 205+the length of the second bonding wire 110. Hence, the wiring may be longer as compared to a configuration in which an electrode on the semiconductor substrate 103 and an electrode on the base 101 are directly connected by a bonding wire, and the electric resistance or the inductance may thus increase. A voltage drop may increase due to the increase of the electric resistance or the like, resulting in a failure in driving of the semiconductor substrate 103. Hence, from the viewpoint of electric wiring, the lengths of the first bonding wire 108, the wiring 206 between the second electrode 204 and the third electrode 205, and the second bonding wire 110 is advantageously short, and its thicknesses is advantageously large. Since the power consumption of the cooling component 200, in turn, the heat flow suppressing effect and the problem about the electric wiring have a tradeoff relationship, the length and thickness of the electric wiring can appropriately be set in accordance with the type of wiring (power supply wiring, ground wiring, signal lines, control lines, and the like).

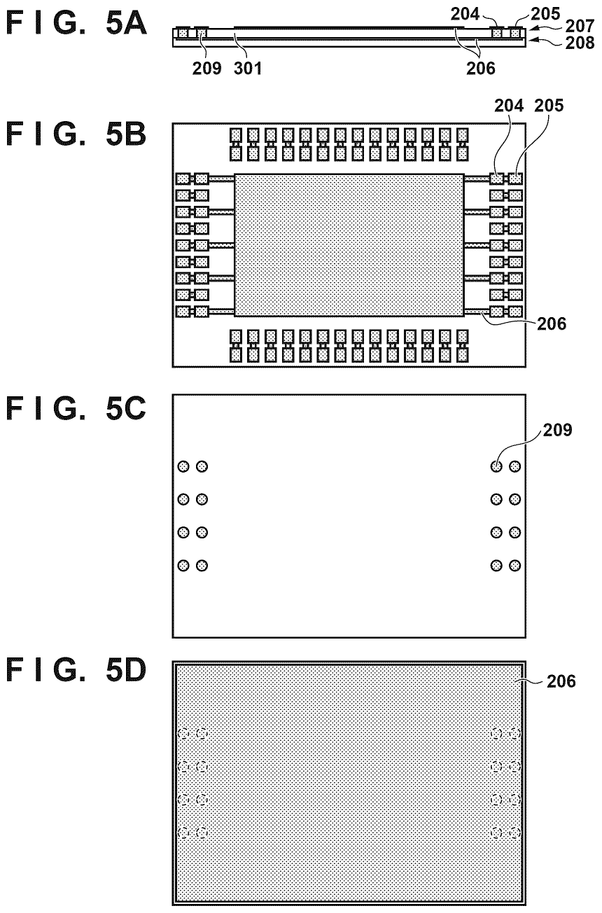

FIGS. 5A to 5D are schematic views for explaining the configuration of the plate member 301 according to this embodiment. FIG. 5A is a schematic sectional view of the plate member 301, and FIGS. 5B to 5D are schematic plan views for explaining the multilayered structure of the plate member 301. The plate member 301 includes a first layer 207 that is a surface layer, and a second layer 208. FIG. 5B is a schematic plan view of the first layer 207. The second electrode 204 and the third electrode 205 are formed, and the second electrode 204 and the third electrode 205 are connected by the wiring 206. Furthermore, some of the second electrodes 204 are connected to a solid pattern wiring region that is a planar conductive layer by forming the wiring 206 extending toward the center inside the plate member 301. The second electrode 204, the third electrode 205, the wiring 206, and the solid pattern wiring region are electrodes of the same potential, and can be, for example, a power supply or ground.

FIG. 5C is a schematic plan view of the intermediate layer between the first layer 207 and the second layer 208. In the intermediate layer, vias 209 configured to connect the wirings 206 of the first layer 207 and the second layer 208 are formed. FIG. 5D is a schematic plan view of the second layer 208. The wiring 206 that is the electrode connected by the vias 209 is formed. For example, if the electrode on which the wiring 206 of the solid pattern is formed in the first layer 207 is the power supply, the wiring 206 formed in the second layer 208 may be ground. When the routing of wirings of the power supply and ground is optimized in the wiring 206 of the plate member 301, the electric resistance and the inductance can be reduced, and the voltage drop can be suppressed.

In addition, at least a part of the wiring 206 arranged in the plate member 301 is arranged to overlap the cooling portion 201 in a planar view, and the wiring 206 can efficiently be cooled. FIGS. 5A to 5D show an example in which the wiring 206 of the solid pattern that is a single type of equipotential electrode is formed in each of the first layer 207 and the second layer 208. A plurality of types of wirings of equipotential electrodes may be in the same layer, or the wiring 206 of the second layer 208 may not be a solid pattern. Also, the multilayered structure of the plate member 301 may include three or more layers.

Additionally, in the first bonding wires 108 and the second bonding wires 110, bonding wires arranged on the electrodes of the power supply and ground may be thicker and shorter than the bonding wires arranged on the electrodes other than the power supply and ground. If the bonding wires are thick or short, the effect of suppressing the voltage drop can be increased. However, in particular, when the second bonding wire 110 is made thick and short, the thermal resistance lowers. For this reason, as compared to a case where all second bonding wires 110 are thin and long, the heat flow suppressing effect may be reduced. To improve the heat flow suppressing effect, the bonding wires arranged on the electrodes other than the power supply and ground may be made thinner or longer.

As described above, the wirings from the semiconductor substrate 103 are electrically connected to the base 101 via the plate member 301 arranged on the cold surface of the cooling component 200, thereby suppressing the heat flow returning from the base 101 to the semiconductor substrate 103. In addition, when the plate member 301 has a multilayered wiring structure, it is possible to reduce the electric resistance or inductance of the wirings and suppress the voltage drop by the wirings.

### Second Embodiment

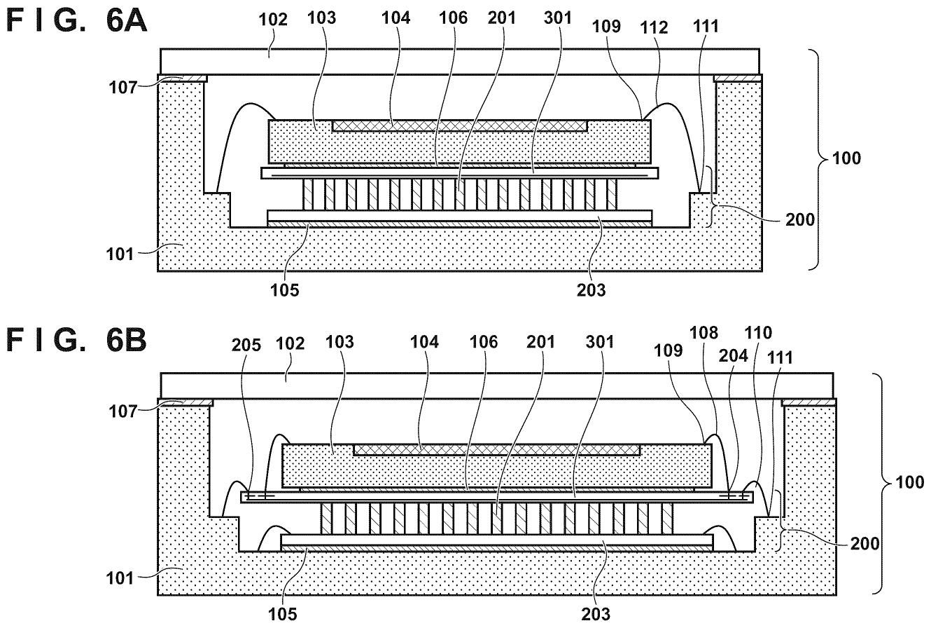

An electronic component according to the second embodiment will be described with reference to FIGS. 6A and 6B to 9. Differences from the first embodiment will mainly be described below, and a description of the same parts as the electronic component according to the first embodiment will not be repeated.

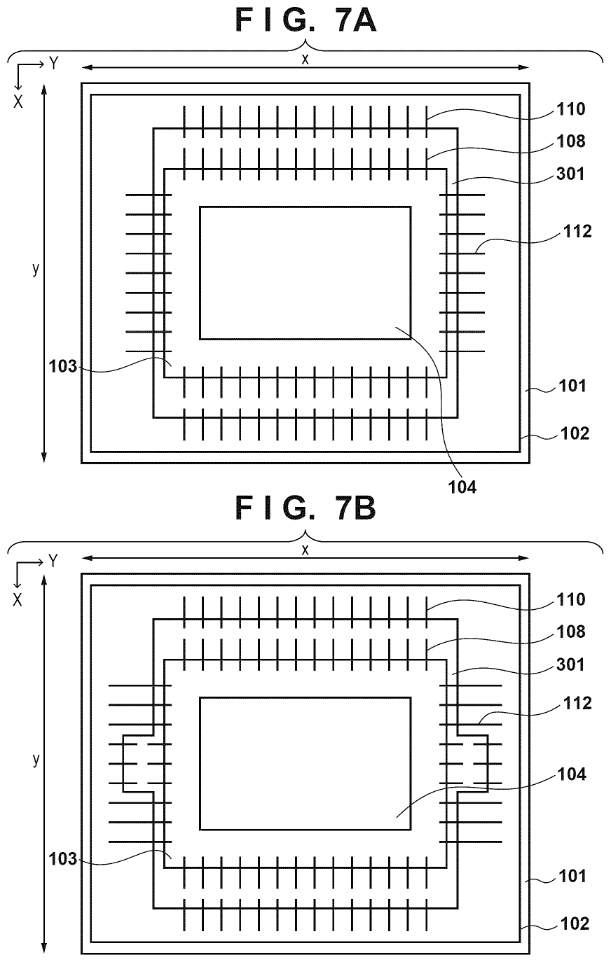

FIGS. 6A and 6B are sectional views showing an example of the configuration of the electronic component according to this embodiment, and FIGS. 7A and 7B show a planar view of the electronic component viewed from the side of an optical member 102. FIG. 6A is a sectional view of the electronic component viewed from the X direction in FIG. 7A, and FIG. 6B is a sectional view of the electronic component viewed from the Y direction in FIG. 7A. The second embodiment is different from the first embodiment in that, as shown in FIG. 6A, bonding wires arranged along the Y direction of the electronic component are not connected to a plate member 301 of a cooling component 200 but are directly connected to a base 101. As for the connection of bonding wires arranged along the X direction of the electronic component shown in FIG. 6B, a first electrode is connected to a fourth electrode 111 via a second electrode 204 and a third electrode 205 of the plate member 301, as in the first embodiment.

The arrangement shown in FIG. 6A will be described. A first electrode 109 formed on a semiconductor substrate 103 and the fourth electrode 111 formed on the base 101 are directly connected by a third bonding wire 112. Since the bonding wire is not connected to the plate member 301, the size of the plate member 301 in the X direction can be reduced. That is, the electronic component can be made compact. First bonding wires 108 or second bonding wires 110 can include, for example, wirings of a power supply or ground. When the routing of wirings of the power supply and ground is optimized in a wiring 206 of the plate member 301, the electric resistance and the inductance can be reduced, and the voltage drop can be suppressed. The third bonding wires 112 may be wirings other than, for example, the power supply and ground. The wirings that affect the voltage drop little are may not connected to the plate member 301. Since a heat flow transmitted to the cooling component 200 can be suppressed because of the decrease of the number of wirings between the electrodes, power consumption of the cooling component 200 can be suppressed.

In this embodiment as well, in the first bonding wires 108, the second bonding wires 110, and the third bonding wires 112, bonding wires arranged on the electrodes of the power supply and ground may be thicker and shorter than the bonding wires arranged on the electrodes other than the power supply and ground. This is because the voltage drop suppressing effect can be improved. Since the third bonding wire 112 directly connects the base 101 and the semiconductor substrate 103, it may be thinner or longer than the first bonding wires 108 and the second bonding wires 110 to improve the heat flow suppressing effect. The length of the third bonding wire 112 can also be adjusted by changing the height of the fourth electrode 111, to which the third bonding wire provided on the base 101 is connected, from the bottom surface.

FIGS. 7A and 7B show planar views of the electronic component according to this embodiment viewed from the side of the optical member 102, and show an example of the arrangement of the first bonding wires 108, the second bonding wires 110, and the third bonding wires 112. As shown in FIG. 7A, all electrodes arranged in the Y direction of the semiconductor substrate 103 may be connected to the base 101 by the third bonding wires 112. Also, as shown in FIG. 7B, concerning the bonding wires connected to the electrodes arranged in the Y direction of the semiconductor substrate 103, the first bonding wires 108, the second bonding wires 110, and the third bonding wires 112 may be mixed. From the viewpoint of reducing the size of the electronic component, the arrangement shown in FIG. 7A, in which the size in the X direction can be reduced, is better than that shown in FIG. 7B, but an appropriate configuration can be selected in accordance with the arrangement of the power supply and ground in the first electrodes 109 on the semiconductor substrate 103. In addition to the arrangements shown in FIGS. 7A and 7B, an arrangement obtained by reversing the X- and Y-direction arrangement shown in FIG. 2 is possible. As a method of mixing the first bonding wires 108, the second bonding wires 110, and the third bonding wires 112, various combinations can be selected.

On the other hand, since the third bonding wire 112 is directly connected from the semiconductor substrate 103 to the fourth electrode 111 on the base 101 without interposing the plate member 301, it may be necessary to form a bonding wire having a high step difference for the connection. When forming the bonding wire having a high step difference, the necessity of considering interference between a capillary that is a tool used for wire bonding and the bonding wire or the base 101 may increase.

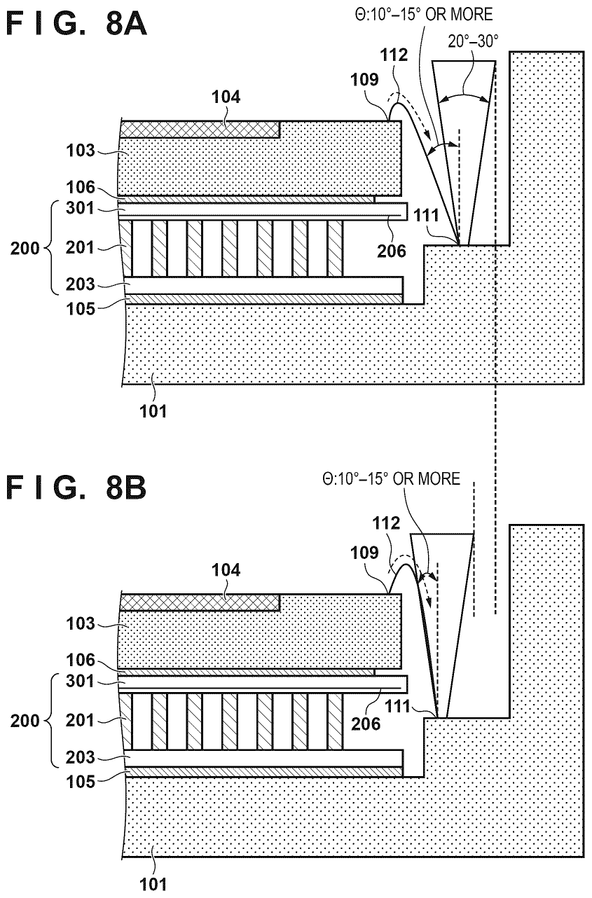

FIGS. 8A and 8B are views for explaining the relationship between a wire angle and a capillary angle during bonding to the base. The angle made by a perpendicular line to the surface on which the fourth electrode 111 is formed and the third bonding wire 112 is defined as a wire angle θ. FIG. 8A is a view in a case where the wire angle θ is larger than 10° to 15°, and FIG. 8B is a view in a case where the wire angle θ is smaller than 10° to 15°.

As shown in FIG. 8A, in general wire bonding, a wire loop is formed after the first electrode 109 on the semiconductor substrate 103 and the third bonding wire 112 are connected, and the fourth electrode 111 on the base 101 and the third bonding wire 112 are connected by stitch bonding. The distal end of the capillary used for bonding at this time normally has an angle of 20° to 30° on the cross section. If bonding is performed in a state in which the wire angle θ is steeper than the angle of the capillary, as shown in FIG. 8B, the capillary and the wire may interfere. Hence, bonding may be impossible. If the wire angle θ is large, it is necessary to ensure a space in the horizontal direction to avoid interference between the fourth electrode 111 and the end portion of the base 101. This space may impede size reduction of the electronic component.

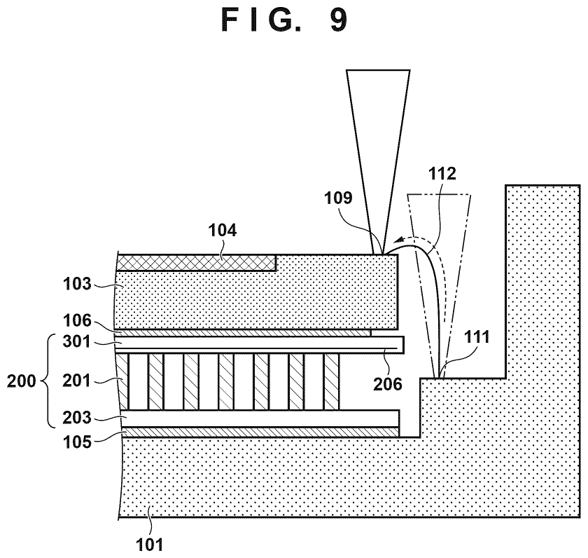

FIG. 9 is a view for explaining the relationship between the wire angle and the capillary angle at the time of wire bonding using the ball-on-stitch-bonding (BSOB) method. In the BSOB method, first, a ball is formed on the first electrode 109. After that, the fourth electrode 111 and the third bonding wire 112 are connected, the capillary is raised almost vertically, and the first electrode 109 and the third bonding wire 112 are connected. That is, balls are formed on both the connection point between the first electrode 109 and the third bonding wire 112 and the connection point between the fourth electrode 111 and the third bonding wire 112, and these are connected. At the connection point between the fourth electrode 111 and the third bonding wire 112, a stitch is formed on the ball, and these are connected.

In the BSOB method, a space in the horizontal direction need only be ensured when connecting the third bonding wire 112 and the fourth electrode 111. According to the BSOB method, when connecting the third bonding wire 112 to the semiconductor substrate 103, no interference occurs between the capillary and the third bonding wire 112 even if no extra distance is ensured between the fourth electrode 111 and the end portion of the base 101. Hence, as compared to a case where the third bonding wire 112 is connected using a normal bonding method, it is possible to reduce the space in the horizontal direction and, in turn, reduce the size of the electronic component. Hence, when forming a bonding wire for connecting a higher step difference as the third bonding wire 112, the BSOB method can be used.

### Third Embodiment

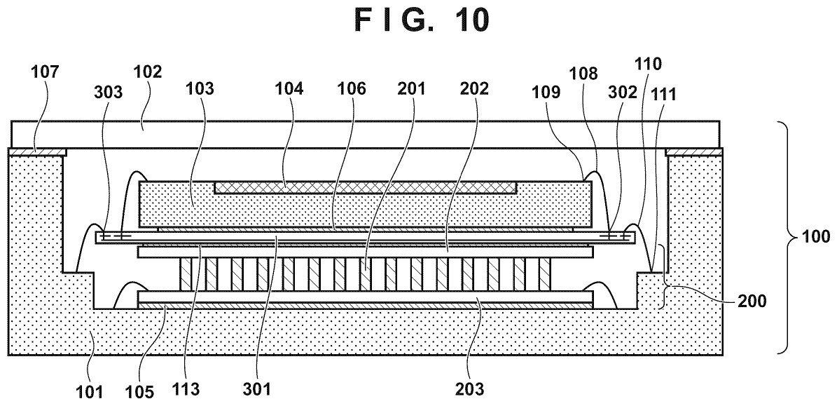

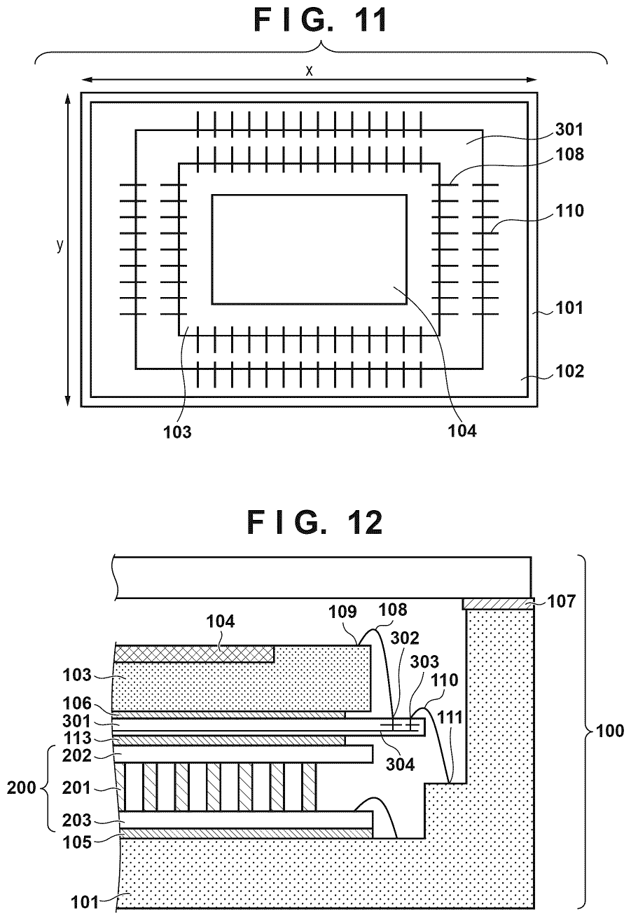

An electronic component according to the third embodiment will be described with reference to FIGS. 10 to 13. Differences from the first and second embodiments will mainly be described below, and a description of the same parts as the electronic components according to the first and second embodiments will not be repeated. FIG. 10 is a sectional view showing an example of the configuration of the electronic component according to this embodiment, and FIG. 11 shows a planar view of the electronic component viewed from the side of an optical member 102. FIG. 12 is a schematic view showing a base 101, a cooling component 200, a plate member 301, and the vicinity of the connection point of a first bonding wire 108 and a second bonding wire 110 of the electronic component according to this embodiment in an enlarged state. The third embodiment is different from the first embodiment in that an upper plate 202 is arranged between the cooling component 200 and the plate member 301. The plate member 301 is arranged on a plate adhesive 113 on the upper plate 202 of the cooling component 200. A semiconductor substrate 103 is arranged on a semiconductor substrate adhesive 106 on the plate member 301. Here, the upper plate 202 of the cooling component 200 is a single-layer plate and may not include wirings. In the plate member 301, a plurality of wirings can be stacked.

The plate member 301 and the upper plate 202 use alumina or aluminum nitride as the main material. The surface may be treated by gold plating or the like to improve heat conduction. As shown in FIG. 12, the plate member 301 includes a fifth electrode 302 and a sixth electrode 303, and a first electrode 109 on the semiconductor substrate 103 and the fifth electrode 302 are connected by the first bonding wire 108. The sixth electrode 303 and a fourth electrode 111 formed on the base 101 are connected by the second bonding wire 110. The fifth electrode 302 and the sixth electrode 303 are connected by a wiring 304, and the semiconductor substrate 103 and the base 101 are electrically connected via the plate member 301. A heat flow transmitted from a lower plate 203 that is a hot surface to the second bonding wire 110 via the base 101 is cooled by the plate member 301 connected to the upper plate 202 cooled by a cooling portion 201. For this reason, the heat flow returning to the semiconductor substrate 103 can be suppressed as compared to a configuration in which an electrode on the semiconductor substrate 103 and an electrode on the base 101 are directly connected by a bonding wire.

In this embodiment, since the plate adhesive 113 and the plate member 301 between the cooling component 200 and the semiconductor substrate 103 may be thermal resistances, as compared to the configuration according to the first embodiment, the effect of suppressing the heat flow may be slightly weaker. For this reason, power consumption may increase. However, when the length or thickness of the bonding wire is taken into consideration, as in the first embodiment, the increase of power consumption or deterioration of the effect of suppressing the heat flow can be suppressed

In the first embodiment, since a wiring needs to be formed in the plate member 301 corresponding to the upper plate of the cooling component 200, the plate member 301 needs to be custom-designed in a case where a Peltier element is used as the cooling component 200. In this embodiment, since no wiring is formed in the upper plate 202 that is a part of a Peltier element, a general-purpose Peltier element can be used as the cooling component 200. When only the plate member 301 is designed/used in accordance with the semiconductor substrate 103, there is an advantage from the viewpoint of cost and versatility.

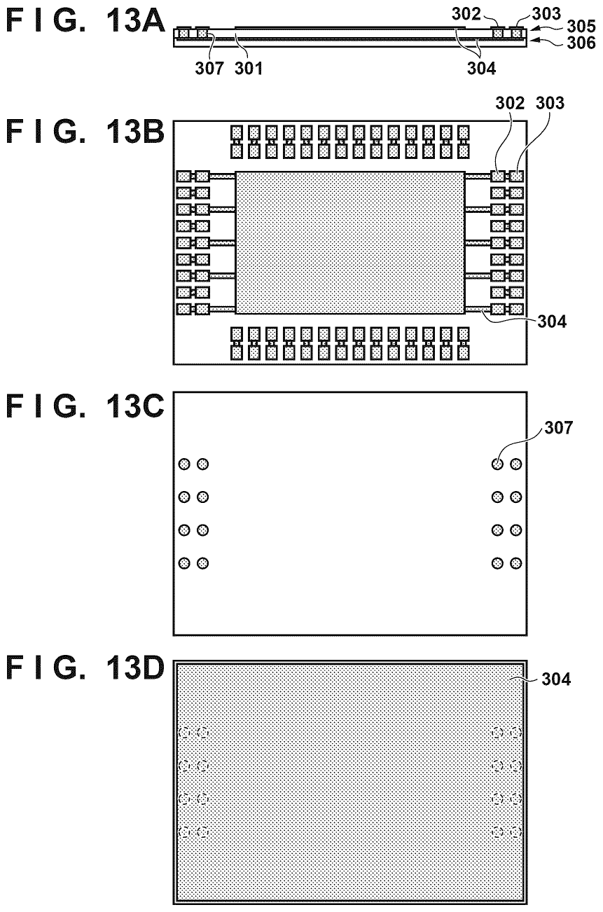

FIGS. 13A to 13D are schematic views of the plate member 301 according to this embodiment. FIG. 13A is a schematic sectional view of the plate member 301, and FIGS. 13B to 13D are schematic plan views of wiring layers stacked in the plate member 301. The configurations of layers are basically the same as in the configuration of the plate member 301 explained with reference to FIGS. 5A to 5D. As shown in FIG. 13A, the plate member 301 includes a first layer 305 that is a surface layer, and a second layer 306. FIG. 13B is a schematic plan view of the first layer 305. The fifth electrode 302 and the sixth electrode 303 are formed, and the fifth electrode 302 and the sixth electrode 303 are connected by the wiring 304. Furthermore, some of the fifth electrodes 302 are connected to a solid pattern wiring region by forming the wiring 304 extending toward the center of the plate member 301. These are electrodes of the same potential and are, for example, a power supply or ground. FIG. 13C is a schematic plan view of the intermediate layer between the first layer 305 and the second layer 306, and vias 307 configured to connect the wirings 304 of the first layer 305 and the second layer 306 are formed.

FIG. 13D is a schematic plan view of the second layer 306. The wiring 304 that is the electrode connected by the vias 307 is formed. For example, if the electrode on which the wiring 304 of the solid pattern is formed in the first layer 305 is the power supply, the wiring 304 formed in the second layer 306 may be ground. When the routing of wirings of the power supply and ground is optimized in the wiring 304 of the plate member 301, the electric resistance and the inductance can be reduced, and the voltage drop can be suppressed. FIGS. 13A to 13D show an example in which the wiring 304 of the solid pattern that is a single type of equipotential electrode is formed in each of the first layer 305 and the second layer 306. A plurality of types of wirings of equipotential electrodes may be in the same layer, or the wiring that is not a solid pattern may be formed. Also, the number of layers may be three or more.

### Fourth Embodiment

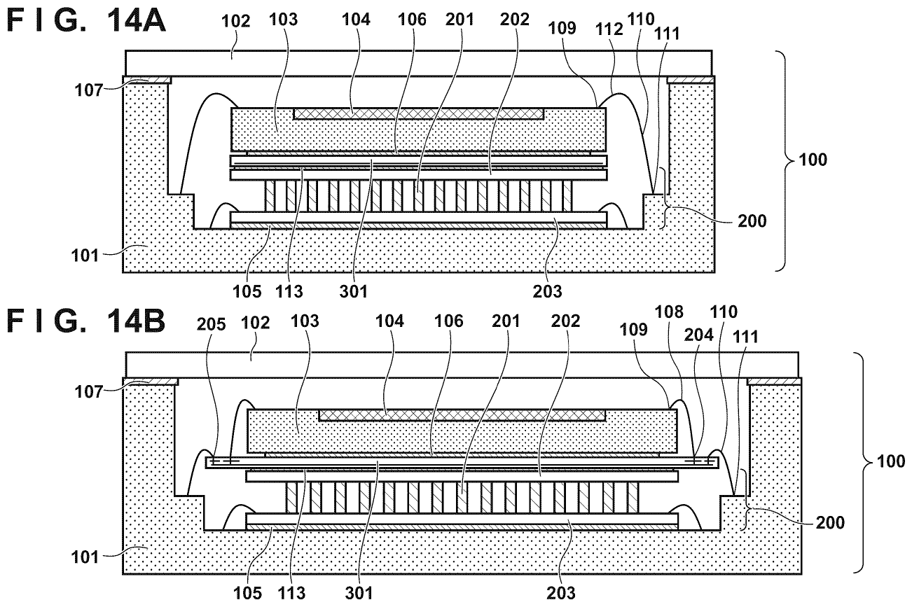

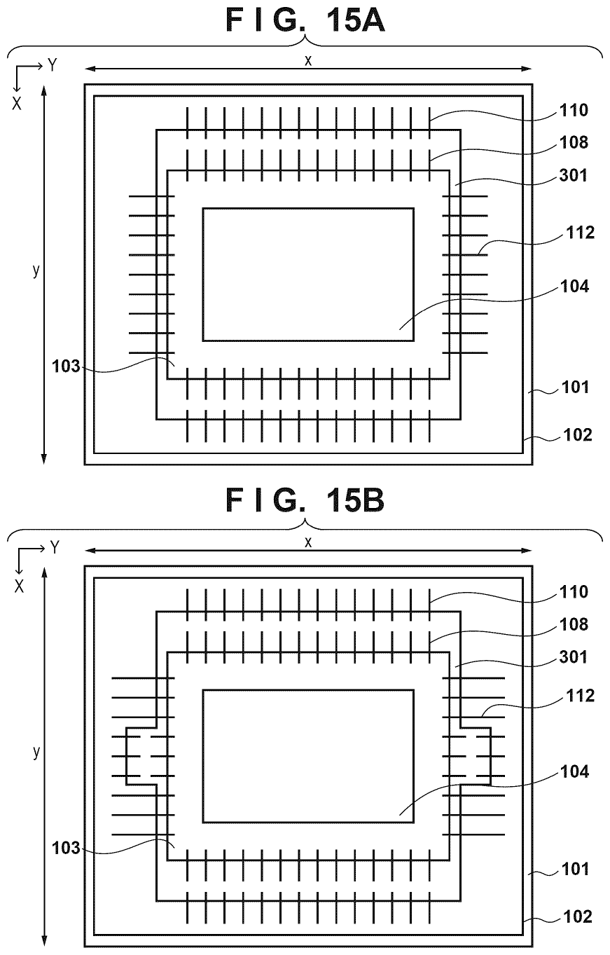

An electronic component according to the fourth embodiment will be described with reference to FIGS. 14A, 14B, 15A and 15B. Differences from the first to third embodiments will mainly be described below, and a description of the same parts as the electronic components according to the first to third embodiments will not be repeated.

FIGS. 14A and 14B are sectional views showing an example of the configuration of the electronic component according to the fourth embodiment, and FIGS. 15A and 15B show planar views of the electronic component viewed from the side of an optical member 102. FIG. 14A is a sectional view of the electronic component viewed from the X direction in FIG. 15A, and FIG. 14B is a sectional view of the electronic component viewed from the Y direction in FIG. 15A. The fourth embodiment is different from the third embodiment in that, as shown in FIG. 14A, bonding wires arranged along the Y direction are not connected to a plate member 301 but are directly connected to a base 101. As for the connection of bonding wires arranged along the X direction shown in FIG. 14B, the bonding wires are connected via the plate member 301, as in the third embodiment. According to the configuration of this embodiment, since the size of the plate member 301 in the X direction can be reduced, like the example of the second embodiment, it is advantageous in making the electronic component compact.

### <Example of Application of Electronic Component to Equipment>

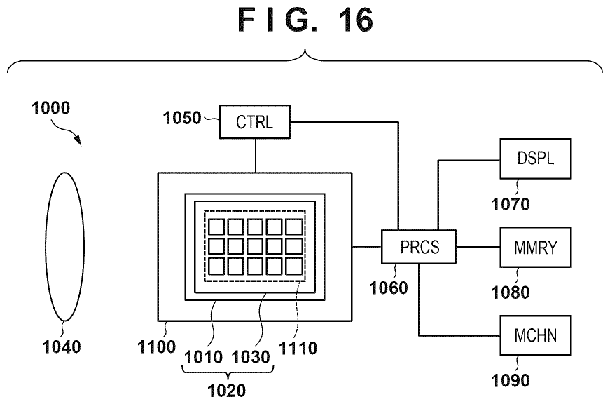

An example in which an electronic component according to an embodiment described above is applied to equipment 1000 will be described with reference to FIG. 16. A semiconductor chip 1110 including an electronic component 1100 including a package 1020 on which the semiconductor chip 1110 is mounted is accommodated in the package 1020 and mounted on the equipment 1000. The electronic component 1100 is an electronic component according to the above embodiment. A cooling component (not shown) is arranged between a base body 1010 of the package 1020 and the semiconductor chip 1110. The electronic component 1100 can include the package 1020 including a base body 1010 of the package 1020 on which the semiconductor chip 1110 is fixed and a light transmissive member 1030 such as glass that faces the semiconductor chip 1110. The package 1020 can be provided with connection members such as wires and bumps that connect inner leads provided on the base body 1010 of the package 1020 to terminals such as pad electrodes provided on the semiconductor chip 1110.

The equipment 1000 can include at least one of an optical apparatus 1040, a control apparatus 1050, a processing apparatus 1060, a display apparatus 1070, a storage apparatus 1080, and a mechanical apparatus 1090. The optical apparatus 1040 is implemented by, for example, a lens, a shutter, and a mirror. The control apparatus 1050 controls the semiconductor chip 1110. The control apparatus 1050 is, for example, a semiconductor device such as an ASIC.

The processing apparatus 1060 processes a signal output from a semiconductor integrated circuit included in the semiconductor chip 1110. The processing apparatus 1060 is a semiconductor device such as a CPU or an ASIC for forming an Analog Front End (AFE) or a Digital Front End (DFE). For example, an image may be generated based on an image capturing signal at the time of detecting an event. The display apparatus 1070 is an EL display device or a liquid crystal display device that displays an information image obtained by the semiconductor chip 1110. The storage apparatus 1080 is a magnetic device or a semiconductor device that stores the information image obtained by the semiconductor chip 1110. The storage apparatus 1080 is a volatile memory such as an SRAM or a DRAM, or a nonvolatile memory such as a flash memory or a hard disk drive.

The mechanical apparatus 1090 includes a moving or propulsion unit such as a motor or an engine. In the equipment 1000, the signal output from the semiconductor chip 1110 is displayed on the display apparatus 1070 or transmitted to an external apparatus by a communication apparatus (not shown) included in the equipment 1000. Hence, the equipment 1000 may further include the storage apparatus 1080 and the processing apparatus 1060 in addition to the memory circuits and arithmetic circuits included in the semiconductor chip 1110. The mechanical apparatus 1090 may be controlled based on the signal output from the semiconductor chip 1110.

The equipment 1000 is suitable for electronic equipment such as an information terminal which has a shooting function, for example, a smartphone or a wearable terminal, or a camera, for example, an interchangeable lens camera, a compact camera, a video camera, or a monitoring camera. The mechanical apparatus 1090 in the camera can drive the components of the optical apparatus 1040 in order to perform zooming, an in-focus operation, and a shutter operation. Alternatively, the mechanical apparatus 1090 in the camera can move the optical apparatus 1040 in order to perform an anti-vibration operation.

Furthermore, the equipment 1000 can be transportation equipment such as a vehicle or a ship. The mechanical apparatus 1090 in the transportation equipment can be used as a moving apparatus. The equipment 1000 as the transportation equipment is suitable for equipment that transports the semiconductor chip 1110 or equipment that uses a shooting function to assist and/or automate drive steering. The processing apparatus 1060 for assisting and/or automating drive steering can perform, based on the information obtained by the semiconductor chip 1110, processing for operating the mechanical apparatus 1090 as a moving apparatus. Alternatively, the equipment 1000 may be medical equipment such as an endoscope, measurement equipment such as a distance measurement sensor, analysis equipment such as an electron microscope, office equipment such as a copy machine, or industrial equipment such as a robot.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2025-026031, filed Feb. 20, 2025 which is hereby incorporated by reference herein in its entirety.

What is claimed is:

1. An electronic component comprising:
a semiconductor substrate; a base; a cooling component, and a plate member including a wiring,
wherein the plate member is arranged between a cold side of the cooling component and the semiconductor substrate,
the base is arranged on a hot side of the cooling component,
a first electrode is arranged on the semiconductor substrate, a second electrode and a third electrode are arranged on the plate member, and a fourth electrode is arranged on the base,
the second electrode and the third electrode are connected by the wiring of the plate member, the first electrode and the second electrode are connected by a first bonding wire, and the third electrode and the fourth electrode are connected by a second bonding wire, and
at least a part of the wiring of the plate member overlaps a region in which the cooling component is arranged in a planar view.

2. The component according to claim 1, wherein the plate member includes a plurality of wiring layers, and
at least a part of a wiring arranged in at least one wiring layer among the plurality of wiring layers overlaps the cooling component in the planar view.

3. The component according to claim 1, wherein the second electrode and the third electrode are arranged outside an outer edge of the semiconductor substrate in a planar view.

4. The component according to claim 1, wherein a plurality of pixels are arranged in the semiconductor substrate.

5. The component according to claim 4, wherein each of the plurality of pixels includes a photoelectric conversion element.

6. The component according to claim 5, wherein the photoelectric conversion element includes an avalanche diode.

7. The component according to claim 1, wherein an optical member is mounted on the base.

8. The component according to claim 1, wherein a first plate is arranged between the plate member and the cooling component, and a second plate is arranged between the hot side of the cooling component and the base.

9. The component according to claim 1, wherein the cooling component is a Peltier element.

10. The component according to claim 1, wherein at least one of the plate member and the base contains at least one of alumina and aluminum nitride.

11. The component according to claim 1, wherein the wiring of the plate member includes a region of a solid pattern.

12. The component according to claim 11, wherein the solid pattern is connected to at least one of electrodes of a power supply and ground.

13. The component according to claim 1, wherein in the first and the second bonding wires, the bonding wires connected to electrodes of a power supply and ground are thicker than bonding wires connected to electrodes other than the power supply and ground.

14. The component according to claim 1, wherein for the first and the second bonding wires, the bonding wires connected to electrodes of a power supply and ground are shorter than bonding wires connected to electrodes other than the power supply and ground.

15. The component according to claim 1, wherein in addition to the first and the second bonding wires, the first electrode and the fourth electrode are connected by a third bonding wire.

16. The component according to claim 15, wherein the third bonding wire is connected to at least an electrode other than a power supply and ground.

17. The component according to claim 15, wherein the third bonding wire has a thermal resistance higher than that of the first bonding wire and the second bonding wire.

18. The component according to claim 15, wherein a connection point between the first electrode and the third bonding wire and a connection point between the fourth electrode and the third bonding wire are formed by ball-on-stitch-bonding.

19. The component according to claim 1, wherein the first bonding wire and the second bonding wire contain at least one of gold and aluminum.

20. Equipment comprising:
an electronic component defined in claim 1; and
a processing apparatus configured to process an output signal from the electronic component.
